(19) United States
(12) Patent Application Publication
(10) Pub. No.: US 2024/0193328 A1
(43) Pub. Date: Jun. 13, 2024

(54) SYSTEM AND METHOD FOR DETERMINING TWO-DIMENSIONAL PATCHES OF THREE-DIMENSIONAL OBJECT USING MACHINE LEARNING MODELS

(71) Applicant: International Institute of Information Technology, Hyderabad, Hyderabad (IN)

(72) Inventors: Avinash Sharma, Hyderabad (IN); Chandradeep Pokhariya, Hyderabad (IN); Shanthika Naik, Hyderabad (IN); Astitva Srivastava, Hyderabad (IN)

(21) Appl. No.: 18/534,578

(22) Filed: Dec. 9, 2023

(30) Foreign Application Priority Data
Dec. 9, 2022 (IN) 202241071267

(51) Int. Cl. G06F 30/27; G06F 30/10

(52) U.S. Cl. CPC G06F 30/27; G06F 30/10

(57) ABSTRACT

A method for determining two-dimensional (2D) patches corresponding to a three-dimensional (3D) object using machine learning models for enabling an improved texture mapping process on the 3D object. The method includes (i) receiving mesh of the 3D object, (ii) training first machine learning model by providing correlation between historic vertices with (a) historic faces, and (b) historic vertex normals of historic meshes based on an objective function of patch extraction, (iii) determining, using the first machine learning model, 2D patches by partitioning the mesh until distortion of the mesh reaches threshold distortion, (iv) training second machine learning model using (i) shape-related features of historic 2D patches associated with historic meshes and (ii) an objective function of surface parameterization of the historic 2D patches associated with the historic meshes, and (v) automatically parameterizing each vertex in the 2D patches to 2D points on 2D plane to enable the texture mapping process.

### CROSS-REFERENCE TO RELATED APPLICATIONS

This patent application claims priority to pending Indian provisional patent application no. 202241071267 filed on Dec. 9, 2022, the complete disclosures of which, in their entirety, are hereby incorporated by reference.

### BACKGROUND

### Technical Field

The embodiments herein generally relate to a surface parameterization of a three-dimensional (3D) object, and more specifically to a method and a system for automatically determining two-dimensional patches corresponding to a three-dimensional (3D) object using machine learning models.

### Description of the Related Art

Ultraviolet (UV) parameterization or UV mapping is a process of mapping a three-dimensional (3D) surface to a two-dimensional (2D) plane. A UV map assigns every point on a surface to a point on the 2D plane, so that a 2D texture can be applied to a 3D object. Determining UV parameterization of arbitrary 3D surfaces lies at the core of computer graphics and geometry processing domain, with a wide range of applications such as 3D modeling, texture mapping, meshing, simulation, etc. The UV parameterization or UV mapping is not a trivial task and demands a solution with specific properties. The UV mapping is expected to be isometric, conformal, and non-overlapping.

Existing conventional methods estimate an object-centric mapping with an iterative optimization process, focusing on minimizing an energy function explicitly constructed to retain the desired properties. However, the existing conventional methods face scalability issues while dealing with high-resolution object meshes and are also prone to local minima. For example, one of the existing conventional methods is a surface parameterization approach, i.e., boundary first flattening that detects one or more cone singularities to cut a 3D object making it bounded, and then parameterizing a surface of the 3D object. However, the surface parameterization approach is not robust to noisy inputs or non-manifold meshes and slows in processing large meshes. Another existing surface parameterization approach, i.e., OptCuts ensures the objective mapping of the parameterization. However, the surface parameterization approach is very slow in processing large meshes. Another existing approach, i.e., least square conformal maps for automatic texture atlas generation parameterizes the surface by minimizing the least square error for the conformal energy. However, the least square conformal approach can only deal with bounded surfaces. Another existing approach, i.e., blender smart ultraviolets (UVs), is fast, however, this approach generates a lot of patches hence a lot more seams.

With the advent of deep learning, some existing methods perform neural-based surface parameterization. However, the neural-based surface parameterization is performed under a supervised learning approach, requiring a large amount of training data. The supervised learning approach gets subjected to data bias and hence suffers from poor generalization to unseen, out-of-distribution samples. Moreover, the existing methods are restricted to only bounded surfaces.

Existing neural-based surface parameterization approach, i.e., neural Jacobian fields is a generalized training-based method for parameterization in a supervised manner which requires pre-processing of a large amount of data. Further, patches need to be homeomorphic to a disc, to be parametrized. The other existing neural-based surface parameterization approaches such as Atlas network (AtlasNet), is a way of surface reconstruction and parameterization by training a neural network to represent a single UV chart over the reconstructed surface. Both approaches use a fixed number of patches for the surface parameterization, however, both approaches require a different neural network for every patch, which is overkill and difficult to scale up.

Another conventional neural-based surface parameterization approach, i.e., AUV-Net takes a point cloud as input and learns parameterization of aligned surfaces (e.g., faces and humans in T-poses) using a cycle-loss, however, requires all the meshes to have similar topology and same orientation to enable learning. Moreover, the proposed two-patch estimation method is very naive and cannot scale to an arbitrary number of patches. Another recent approach learns the intrinsic mapping of arbitrary surfaces in a supervised setup, where a conventional method acts as the ground truth. However, it can only deal with bounded surfaces and does not provide its provision for unbounded surfaces (e.g., spheres).

Therefore, there arises a need to address the aforementioned technical drawbacks in existing technologies.

### SUMMARY

In view of the foregoing, an embodiment herein provides a processor-implemented method for automatically determining a plurality of two-dimensional (2D) patches corresponding to a three-dimensional (3D) object using machine learning models for enabling an improved texture mapping process on the 3D object. The method includes receiving a mesh of the 3D object through a user device. The mesh includes a set of vertex positions or vertices, a set of faces that connect the set of vertex positions, a set of normals, and a set of vertex normals. The method includes training a first machine learning model by providing a correlation between historic vertices with (a) historic faces, and (b) historic vertex normals of historic meshes based on an objective function of patch extraction as first training data. The method includes determining, using the first machine learning model, one or more 2D patches by partitioning the mesh until a distortion of the mesh reaches a threshold distortion. Each 2D patch includes a subset of vertices, a subset of faces that are associated with the subset of vertices, and a subset of face normal. The first machine learning model correlates the subset of vertices with (a) the subset of faces that are associated with the subset of vertices, and (b) the subset of face normals and is retrained using the correlation between the one or more 2D patches with the first training data to improve determination of the one or more 2D patches of the mesh. The method includes training a second machine learning model using (i) shape-related features of historic 2D patches associated with the historic meshes and (ii) an objective function of surface parameterization of the historic two-dimensional patches associated with the historic meshes as second training data. The method includes automatically parameterizing each vertex in the plurality of 2D patches to two-dimensional (2D) points on a two-dimensional (2D) plane to enable the texture mapping process on the 3D object, the second machine learning model is retrained by providing parameterized vertex of the plurality of 2D patches in the 2D points on the 2D plane to improve the texture mapping process further on the 3D object.

In some embodiments, the objective function of the patch extraction includes at least one of a cosine similarity constraint or a geodesic distance constraint. The cosine similarity constraint is determined by calculating a cosine similarity between normal vectors of the historic faces within the historic meshes. The geodesic distance constraint is determined by calculating a shortest path between the historic vertices within the historic meshes based on the cosine similarity between the normal vectors of the historic faces.

In some embodiments, the second machine learning model includes a forward mapping network that is associated with a diffusion block and a backward mapping network.

In some embodiments, the method further includes mapping each vertex to the 2D points on the 2D plane by (i) receiving a subset of vertices of the one or more 2D patches through the forward mapping network, (ii) processing, using the backward mapping network, the subset of vertices through the diffusion block to obtain the shape-related features or relationships between one or more features of the one or more 2D patches, and (iii) mapping each vertex to the 2D points on the 2D plane based on the overall shape-related features of the one or more bound patches.

In some embodiments, the method further includes the backward mapping network predicts a three-dimensional position of the 2D points that matches the set of vertices of the mesh.

In some embodiments, the objective function of the surface parameterization includes at least one of a cycle consistency loss, an isometric loss, an angle preservation loss, or an area preservation loss.

In some embodiments, the method further includes partitioning the mesh by (i) receiving the set of vertex normals and the set of vertices of the mesh, (ii) predicting probabilities of the set of vertices associated with the one or more 2D patches by processing the set of vertex normals and the set of vertices, (iii) obtaining the probabilities of the set of faces by averaging neighboring probabilities of the set of vertices for each face, and (iv) partitioning the mesh by assigning the set of faces into the one or more 2D patches based on the probabilities of the set of vertices. The probabilities of the set of vertices are predicted by analyzing surface characteristics of the mesh at a multi-scale characterization.

In some embodiments, the method further includes implementing the multi-scale characterization by determining the one or more features from the set of vertices of the mesh at a finer level or a coarse level by analyzing the mesh using a diffusion network in the first machine learning model.

In some embodiments, the mesh includes a single patch if the surface of the mesh has a low variability in an extrinsic curvature.

In one aspect, a system for automatically determining a plurality of two-dimensional (2D) patches corresponding to a three-dimensional (3D) object using machine learning models for enabling an improved texture mapping process on the 3D object is provided. The system includes a flat surface of a server. The server receives a mesh of the 3D object through a user device. The mesh includes a set of vertex positions or vertices, a set of faces that connect the set of vertex positions, a set of normals, and a set of vertex normal. The server includes a memory that stores a set of instructions and a processor that executes the set of instructions. The processor is configured to train a first machine learning model by providing a correlation between historic vertices with (a) historic faces, and (b) historic vertex normals of historic meshes based on an objective function of patch extraction as first training data. The processor is configured to determine, using the first machine learning model, one or more 2D patches by partitioning the mesh until a distortion of the mesh reaches a threshold distortion. Each 2D patch includes a subset of vertices, a subset of faces that are associated with the subset of vertices, and a subset of face normal. The first machine learning model correlates the subset of vertices with (a) the subset of faces that are associated with the subset of vertices, and (b) the subset of face normals and is retrained using the correlation between the one or more 2D patches with the first training data to improve determination of the one or more 2D patches of the mesh. The processor is configured to train a second machine learning model using (i) shape-related features of historic 2D patches associated with the historic meshes and (ii) an objective function of surface parameterization of the historic two-dimensional patches associated with the historic meshes as second training data. The processor is configured to automatically parameterize each vertex in the plurality of 2D patches to two-dimensional (2D) points on a two-dimensional (2D) plane to enable the texture mapping process on the 3D object, the second machine learning model is retrained by providing parameterized vertex of the plurality of 2D patches in the 2D points on the 2D plane to improve the texture mapping process further on the 3D object.

In some embodiments, the objective function of the patch extraction includes at least one of a cosine similarity constraint, or a geodesic distance constraint. The cosine similarity constraint is determined by calculating a cosine similarity between normal vectors of the historic faces within the historic meshes. The geodesic distance constraint is determined by calculating a shortest path between the historic vertices within the historic meshes based on the cosine similarity between the normal vectors of the historic faces.

In some embodiments, the second machine learning model includes a forward mapping network that is associated with a diffusion block, and a backward mapping network.

In some embodiments, the processor is configured to map each vertex to the 2D points on the 2D plane by (i) receiving a subset of vertices of the one or more 2D patches through the forward mapping network, (ii) processing, using the backward mapping network, the subset of vertices through the diffusion block to obtain the shape-related features or relationships between one or more features of the one or more 2D patches, and (iii) mapping each vertex to the 2D points on the 2D plane based on the shape-related features of the one or more 2D patches.

In some embodiments, the backward mapping network predicts a three-dimensional position of the 2D points that matches with the set of vertices of the mesh.

In some embodiments, the objective function of the surface parameterization includes at least one of a cycle consistency loss, an isometric loss, an angle preservation loss, or an area preservation loss.

In some embodiments, the processor is configured to partition the mesh by (i) receiving the set of vertex normals and the set of vertices of the mesh, (ii) predicting probabilities of the set of vertices associated with the one or more 2D patches by processing the set of vertex normals and the set of vertices, (iii) obtaining the probabilities of the set of faces by averaging neighboring probabilities of the set of vertices for each face, and (iv) partitioning the mesh by assigning the set of faces into the one or more 2D patches based on the probabilities of the set of vertices. The probabilities of the set of vertices are predicted by analyzing surface characteristics of the mesh at a multi-scale characterization.

In some embodiments, the processor is configured to implement the multi-scale characterization by determining the one or more features from the set of vertices of the mesh at a finer level or a coarse level by analyzing the mesh using a diffusion network in the first machine learning model.

In some embodiments, the mesh includes a single patch if the surface of the mesh has a low variability in an extrinsic curvature.

In another aspect, one or more non-transitory computer-readable storage mediums configured with instructions executable by one or more processors to cause the one or more processors to perform a method of automatically determining one or more two-dimensional (2D) patches corresponding to a three-dimensional (3D) object using machine learning models for enabling an improved texture mapping process on the 3D object. The method includes receiving a mesh of the 3D object through a user device. The mesh includes a set of vertex positions or vertices, a set of faces that connect the set of vertex positions, a set of normals, and a set of vertex normals. The method includes training a first machine learning model by providing a correlation between historic vertices with (a) historic faces, and (b) historic vertex normals of historic meshes based on an objective function of patch extraction as first training data. The method includes determining, using the first machine learning model, one or more 2D patches by partitioning the mesh until a distortion of the mesh reaches a threshold distortion. Each 2D patch includes a subset of vertices, a subset of faces that are associated with the subset of vertices, and a subset of face normal. The first machine learning model correlates the subset of vertices with (a) the subset of faces that are associated with the subset of vertices, and (b) the subset of face normals and is retrained using the correlation between the one or more 2D patches with the first training data to improve determination of the one or more 2D patches of the mesh. The method includes training a second machine learning model using (i) shape-related features of historic 2D patches associated with the historic meshes and (ii) an objective function of surface parameterization of the historic two-dimensional patches associated with the historic meshes as second training data. The method includes automatically parameterizing each vertex in the plurality of 2D patches to two-dimensional (2D) points on a two-dimensional (2D) plane to enable the texture mapping process on the 3D object, the second machine learning model is retrained by providing a parameterized vertex of the plurality of 2D patches in the 2D points on the 2D plane to improve the texture mapping process further on the 3D object.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 illustrates a system 100 for automatically determining one or more two-dimensional patches corresponding to a three-dimensional (3D) object using machine learning models according to some embodiments herein;

FIG. 2 illustrates a block diagram of a server 106 of the system of FIG. 1 according to some embodiments herein;

FIG. 3 is an exemplary diagram for determining one or more two-dimensional patches corresponding to a three-dimensional (3D) object using machine learning models according to some embodiments herein;

FIG. 4 is an exemplary diagram of surface parameterization for bounded patch and unbounded patch of the three-dimensional (3D) object according to some embodiments herein;

FIG. 5 is an exemplary diagram that illustrates a qualitative comparison between the system and existing systems based on Quasi-Conformal Error (QCE) and Area Scale Error (ASE) metrics on a texture of a parameterized surface of an input mesh on specific classes of a Shape Retrieval Contest (SHREC) dataset according to some embodiments herein;

FIG. 6 is an exemplary diagram of an impact of incorporating the geodesic loss (Lgeo) into an objective function of patch extraction according to some embodiments herein;

FIG. 7 is an exemplary diagram of the impact of using global shape encoding Vs per-vertex features by the diffusion block of a second machine learning model in regularizing a three-dimensional (3D) position of 2D points (u) of the one or more 2D patches in the two-dimensional (2D) plane during surface parameterization according to some embodiments herein;

FIG. 8 is an exemplary diagram of an ablation of different losses in the second machine learning model during training of the surface parameterization of the input mesh parameterization according to some embodiments herein;

FIG. 9 is an exemplary diagram of obtaining one or more 2D patches from unbounded surfaces and how the one or more 2D patches impact conformal and angular distortion in the surface parameterization of the input mesh according to some embodiments herein;

FIG. 10 is a flow diagram that illustrates a method for automatically determining one or more two-dimensional (2D) patches corresponding to a three-dimensional (3D) object using machine learning models according to some embodiments herein; and

FIG. 11 is a schematic diagram of a computer architecture in accordance with the embodiments herein.

### DETAILED DESCRIPTION OF THE DRAWINGS

The embodiments herein and the various features and advantageous details thereof are explained more fully with reference to the non-limiting embodiments that are illustrated in the accompanying drawings and detailed in the following description. Descriptions of well-known components and processing techniques are omitted. so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

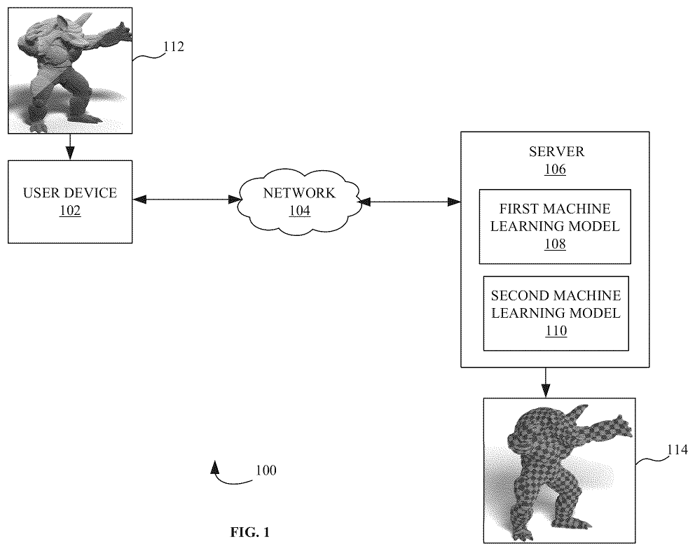

As mentioned, there remains a need for a method and a system for automatically determining two-dimensional (2D) patches corresponding to a three-dimensional (3D) object using machine learning models for enabling an improved texture mapping process on the 3D object according to some embodiments herein. Referring now to the drawings, and more particularly to FIGS. 1 through 11 where similar reference characters denote corresponding features consistently throughout the figures, there are shown preferred embodiments.

FIG. 1 illustrates a system 100 for automatically determining a plurality of two-dimensional (2D) patches corresponding to a three-dimensional (3D) object using machine learning models according to some embodiments herein. The system 100 includes a user device 102 associated with a user, and a server 106. The server 106 includes a first machine learning model 108 and a second machine learning model 110. A list of devices that are capable of hosting the server 106, without limitation, may include one or more personal computers, laptops, tablet devices, smartphones, mobile communication devices, personal digital assistants, or any other such computing device.

The user device 102, without limitation, may include a mobile phone, a kindle, a PDA (Personal Digital Assistant), a tablet, a music player, a computer, an electronic notebook, or a smartphone. The server 106 may communicate with the user device 102 through a network 104. In some embodiments, the network 104 is a wireless network or a wireless network. In some embodiments, the network 104 is a combination of a wired network and a wireless network. In some embodiments, the network 104 is an Internet. The mesh of the 3D object 112 is a collection of a set of vertex positions or vertices (v), a set of faces (F) that connect the set of vertex positions, and a set of normals (NF) and a set of vertex normals (NV) that defines a shape of the 3D object. The mesh of the 3D object 112 may be a high extrinsic curvature or unbounded surface. The mesh may be triangular, quadrilateral, or N-gon. The vertices are individual points in a 3D space that define corners or intersections of the mesh. The vertices are represented by their coordinates (x, y, z). The faces or polygons are flat, or 2D shapes formed by connecting the set of vertices with edges of the 3D object. The vertex normals are associated with the vertices. The normals at the vertex are used to interpolate normals across the faces of polygons connected to that vertex.

The server 106 receives the mesh of the 3D object 112 through the user device 102. The server 106 trains a first machine learning model by providing a correlation between historic vertices with (a) historic faces, and (b) historic vertex normals of historic meshes based on an objective function of patch extraction as first training data. The server 106 determines 2D patches by partitioning the mesh until a distortion of the mesh reaches a threshold distortion using the first machine learning model.

The distortion in the mesh means the degree to which the original shape or structure of the mesh has been altered or deviates from an ideal state. Each patch (P_{K}) includes a subset of vertices (Vₖ), a subset of faces (Fₖ) that is associated with the subset of vertices, and a subset of face normals (N_{Fk}). Each patch is a region or area within the mesh that is surrounded by a border of pixels. Each patch (P_{K}) is represented as (P_{K})={Vₖ, Fₖ, N_{Fk}). where k={1, 2, . . . K), where Vₖ⊆V is the set of vertices belonging to Pₖ. Where Fₖ⊆F is the set of faces defined on Vk and N_{Fk}⊆NF is a set of face normals associated with the set of faces. The first machine learning model 108 may be a patch network (PatchNet) (ϕpatch). Where K is a variable or a controllable parameter that represents the number of patches. The variable K can vary based on an acceptable amount of distortion in the mesh that is inputted by the user device 102. In some embodiments, the server 106 partitions the mesh of the 3D object 110 into one or more 2D patches based on an acceptable amount of distortion in the mesh which means a degree of distortion that is considered, or suitable within the predefined limits for more efficient partitioning the mesh 112.

The server 106 determines the 2D patches by partitioning the mesh until a distortion of the mesh reaches a threshold distortion using the first machine learning model. Each 2D patch includes a subset of vertices, a subset of faces that are associated with the subset of vertices, and a subset of face normals. The server 106 partitions the mesh of the 3D object 112 by (i) receiving the set of vertex normals (N_{V}) and the set of vertices (v) of the mesh, (ii) predicting probabilities of the set of vertices (Vₖ) associated to the one or more 2D patches by processing the set of vertex normals (N_{V}) and the set of vertices (Vₖ), (iii) obtaining the probabilities of the set of faces (F) by averaging neighbouring probabilities of the set of vertices (Vₖ) for each face, and (iv) partitioning the mesh of the 3D object 112 by assigning the set of faces into the one or more bound patches based on the probabilities of the set of vertices. The one or more 2D patches are flat. In some embodiments, the server 106 inputs the mesh 112 into the PatchNet. The PatchNet determines the predicted assignment probability for all the vertices to each of the K patches. The probabilities of the set of faces (F) or per-face probabilities are obtained by taking the mean probabilities of the corresponding face vertices. The per-face probabilities are consolidated by taking an average over neighbouring faces. Each face is assigned to the one or more bound patches with the highest probability.

The probabilities of the set of vertices are predicted by analyzing surface characteristics of the mesh of the 3D object 112 at a multi-scale characterization. The multi-scale characterization is implemented by determining the one or more features from the set of vertices of the mesh at a finer level or a coarse level by analyzing the mesh using a diffusion network in the first machine learning model 108. The multi-scale characterization includes features of the mesh of the 3D object 112 at different levels (i.e., from a global level to a local level). The multi-scale characterization could include analyzing the mesh of the 3D object 112 at various resolutions and capturing both fine details like surface textures and coarse details like overall shape characteristics.

The server 106 trains the first machine learning model 108 by correlating the subset of vertices with (a) the subset of faces that are associated with the subset of vertices, and (b) the subset of face normals of historic meshes based on an objective function of patch extraction as first training data. The objective function of the patch extraction includes a cosine similarity constraint (Lcos), or a geodesic distance constraint (Lgeo). The cosine similarity constraint is determined (Lcos) by calculating cosine similarity between normal vectors of the historic faces within the historic meshes to minimize the following cosine similarity constraint on the historic patches,

$${ℒ}_{cos} = {\sum }_{k = 1}^{K} {\frac{1}{\vert {ℱ}_{k} \vert} [ 1 - ( {\sum }_{i , j ∈ {ℱ}_{k}} ( {\hat{n}}_{i}^{T} {\hat{n}}_{j} ) ) ]}^{2}$$

where i, j∈Fₖ are pair of faces with unit normal vectors n\hat{ }i, n\hat{ }j∈N_{Fk}, respectively, and |Fₖ| is the number of faces in the historic patches.

The geodesic distance constraint ( [symbol] _{geo}) is determined by calculating a shortest path between the historic vertices within the historic meshes based on the cosine similarity between the normal vectors of the historic faces of the historic meshes.

$${ℒ}_{geo} = {\sum }_{k = 1}^{K} \frac{1}{\vert {𝒫}_{k} \vert} ( {\sum }_{i , j ∈ {𝒱}_{k}} g ( i , j ) )$$

Where a geodesic distance is denoted by g(i, j), between the pair of vertices (i and j) within the historic patches. where |Pk| is the number of vertices in the historic patches. vertices within the same patch, taking into account the underlying surface structure.

The objective function for patch extraction Lpatch=λ_{cos}L_{cos}+λ_{geo}L_{geo}. The objective function for patch extraction controls the training process to minimize both the cosine similarity constraint and the geodesic distance constraint for effective patch extraction or partition.

The server 106 trains the second machine learning model 110 using (i) shape-related features of historic 2D patches associated with the historic meshes and (ii) an objective function of surface parameterization of the historic two-dimensional patches associated with the historic meshes as second training data.

The server 106 automatically parameterizes each vertex in the 2D patches to two-dimensional (2D) points on a two-dimensional (2D) plane using the second machine learning model 110, thereby enabling the texture mapping process on the 3D object 112. The 2D plane may be an ultraviolet (UV) plane. The second machine learning model 110 parametrizes each patch Pk={Vₖ, Fₖ, Nₖ} separately. The second machine learning model 110 is multi-layer perceptrons (MLPs). The MLPs may include a forward mapping network (MLPf) associated with a diffusion block, and a backward mapping network (MLP_{f}⁻¹). A mapping function, denoted as f: R³→R² each vertex v∈Vₖ to a 2D point (u) on the UV plane. The mapping function (f) is represented by the forward mapping network (MLP_{f}) with learnable parameters (ϕ_{f}).

The MLPs are conditioned with the diffusion-based global shape encoding ψ to regularize a three-dimensional (3D) position of the 2D points (u) and enhance the output of MLPf−1. The server 106 maps each vertex to the 2D points (u) on the 2D plane by (i) receiving the set subset of vertices (Vk) of the one or more bound patches through the forward mapping network, (ii) processing the set subset of vertices (Vk) through a diffusion block using the backward mapping network (MLP_{f}⁻¹) to obtain an shape-related features or relationships between one or more features of the one or more bound patches, and (iii) mapping each vertex to the 2D points (u) on the 2D plane based on the overall shape-related features of the one or more bound patches.

The set of vertices (Vk) processed through the diffusion block to obtain the overall shall related features or global shape encoding ψ∈R¹²⁸. The input 112 per vertex provided to the forward mapping network (MLP_{f}) is ∈R131 (v concatenated with ψ). The forward mapping network (MLP_{f}) provides an output is u∈R2 that represents UV coordinates i.e., u=MLPf (z).

The backward mapping network (MLP_{f}⁻¹) with learnable parameters (ϕf⁻¹) for backward mapping (f⁻¹:R²→R³). The backward mapping network (MLP_{f}⁻¹) receives a 2D point (u) as input and predicts corresponding three-dimensional (3D) position of the 2D points (u) that matches with the set of vertices of the mesh which means consistency between the forward mapping network (MLP_{f}) and the backward mapping network (MLP_{f}⁻¹) is enforced by minimizing a cycle loss,

$${ℒ}_{cycle} = \frac{1}{\vert {𝒱}_{k} \vert} {\sum }_{v ∈ {𝒱}_{k}} {( v - {MLP}_{{f}^{- 1}} ( u ) )}^{2}$$

The cycle loss ensures that (MLP_{f}⁻¹) and MLPf (z) closely approximate the original input (Z). The original input (Z) is a concatenation of a vertex (v) and the global shape encoding (ψ).

The objective function of the surface parameterization includes a cycle consistency loss (Lcycle), an isometric loss (Liso), an angle preservation loss (Langle), or an area preservation loss (Larea). The objective function of the surface parameterization is Luv=λ₁L_{cycle}+λ₂Liso+λ₃L_{angle}+λ₄Lₐᵣₑₐ.

The final objective function for surface parameterization is Lₚₐᵣₐₘ=λ_{cycle}L_{cycle}+λᵢₛₒLᵢₛₒ+λ_{angle}L_{angle}+λₐᵣₑₐLₐᵣₑₐ.

where ∥·∥ represents the L2 norm. This loss is imposed only on geodesic distances less than a certain threshold σ. For example, σ=0.2. The isometric loss (Lᵢₛₒ) is designed to impose an isometric constraint in the UV space. The isometric loss (Lᵢₛₒ) ensures that the geodesic distance (Gd) between a pair of vertices in 3D space G_{d} ∈R^{V×V} is equal to the Euclidean distance (Ed) in the E_{d}∈R^{V×V} UV space by _{Liso}=∥G_{d}, E_{d}∥.

The angle loss is utilized to minimize conformal error in the UV space by L₂ norm between the angles θ³ᵢ−=1 per face belonging to F in the 3D space and the corresponding faces and the corresponding faces in the UV space. For example, θ³ᵢ−=1 represents the angles of a face in 3D space and f represents the corresponding face in the UV space, the angle loss might be

$${ℒ}_{angle} = \frac{1}{\vert F \vert} {\sum }_{j = 1}^{j = \vert F \vert} \frac{1}{3} {\sum }_{i = 1}^{3} {( cos ( {f}_{{θ}_{i}}^{j} ) - cos ( {F}_{{θ}_{i}}^{j} ) )}^{2}$$

where |F| is total the number of faces. Similarly, Larea loss is used to minimise the area distortion by taking an L2 norm between the areas ap, aq of the faces f in the 3D space and faces F in UV space, respectively. The area loss is

$${ℒ}_{area} = \frac{1}{\vert F \vert} {\sum }_{{a}_{p} , {a}_{q} ∈ f , F} {( {a}_{p} , {a}_{q} )}^{2}$$

The first machine learning model 108 and the second machine learning model 110 are trained based on discretization-agnostic UV parameterization learning.

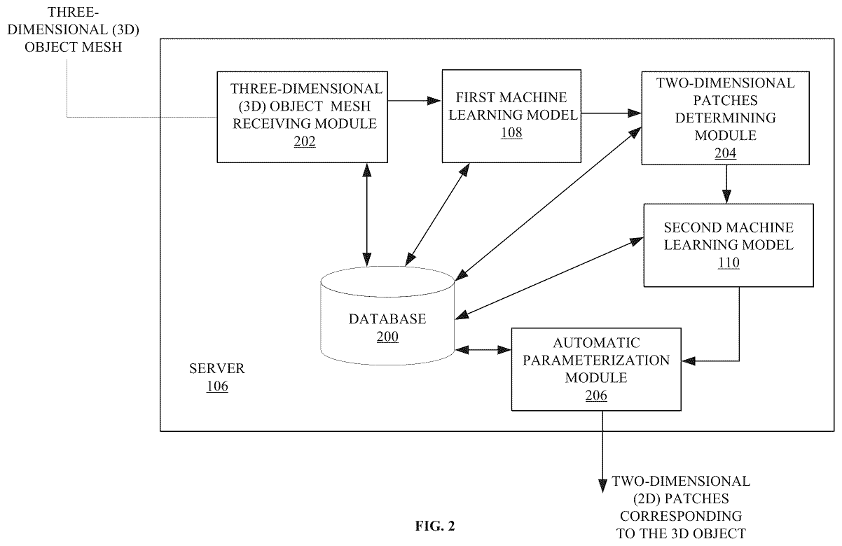

FIG. 2 illustrates a block diagram of the server 106 of the system 100 of FIG. 1 according to some embodiments herein. The server 106 includes a three-dimensional (3D) object mesh receiving module 202, a first machine learning model 108, a two-dimensional (2D) patches determining module 204, a second machine learning model 110, an automatic parameterization module 206, and a database 200. The 3D object mesh receiving module 202 receives a mesh of the 3D object through a user device. The mesh includes a set of vertex positions or vertices, a set of faces that connect the set of vertex positions, a set of normals, and a set of vertex normals. The first machine learning model 108 is trained by providing a correlation between historic vertices with (a) historic faces, and (b) historic vertex normals of historic meshes based on an objective function of patch extraction as first training data. The two-dimensional (2D) patches determining module 204 determines the 2D patches by partitioning the mesh until a distortion of the mesh reaches a threshold distortion using the first machine learning model 108. Each 2D patch includes a subset of vertices, a subset of faces that is associated with the subset of vertices, and a subset of face normal. The first machine learning model 108 correlates the subset of vertices with (a) the subset of faces that are associated with the subset of vertices, and (b) the subset of face normals and is retrained using the correlation between the plurality of 2D patches with the first training data to improve determination of the 2D patches of the mesh. The second machine learning model 110 is trained by using (i) shape-related features of historic 2D patches associated with the historic meshes and (ii) an objective function of surface parameterization of the historic two-dimensional patches associated with the historic meshes as second training data. The second machine learning model 110 automatically parameterizes each vertex in the 2D patches to two-dimensional (2D) points on a two-dimensional (2D) plane to enable the texture mapping process on the 3D object. The second machine learning model is retrained by providing parameterized vertex of the plurality of 2D patches in the 2D points on the 2D plane to improve the texture mapping process further on the 3D object.

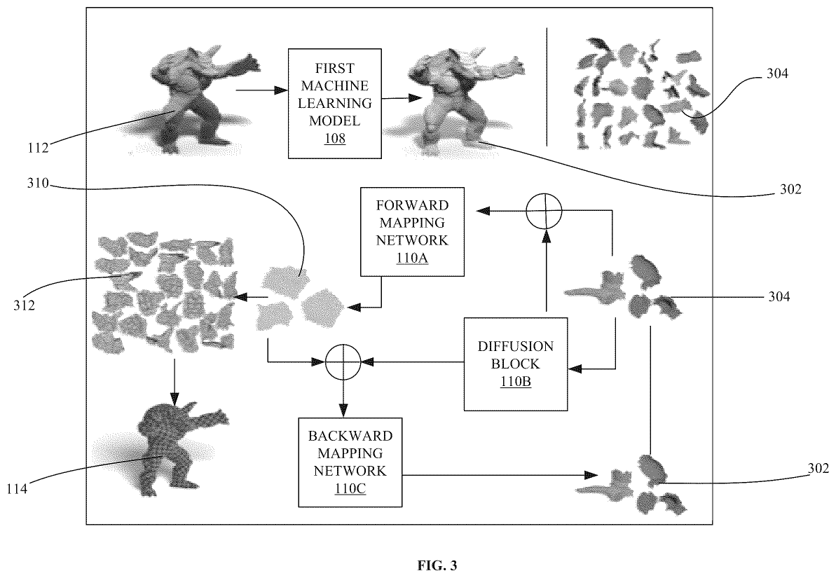

FIG. 3 is an exemplary diagram for determining one or more two-dimensional patches corresponding to a three-dimensional (3D) object using machine learning models according to some embodiments herein. The exemplary diagram depicts the mesh of the 3D object at 112 that is received through the user device 102. The mesh of the 3D object 112 is inputted into the first machine learning model 108. The first machine learning model 108 partitions the mesh of the 3D object 112 into one or more 2D patches that are depicted at 304 by determining an output depicted at 302 which is the predicted assignment probability for all the vertices to each of the K patches. The predicted assignment probability is the set of vertices of the mesh that belongs to a specific category (i.e., the probability of vertices being assigned to each of the K patches or subset). The subset of vertices (Vk) of the one or more bound patches 304 are inputted to the forward mapping network 110A of the second machine learning model 110. The set subset of vertices (Vk) of the one or more bound patches 304 are processed by the diffusion block 110B associated with the forward mapping network 110A. The forward mapping network 110A determines the flat surface of one or more 2D patches of the 3D object depicted at 310 which is determined by mapping each vertex (Vk) in the one or more 2D patches to two-dimensional (2D) points on the two-dimensional (2D) plane. The flat surface of one or more 2D patches 310 is textured by the user. The textured flat surface of one or more 2D patches 310 is reconstructed as the 3D object with textured geometry depicted at 114 by the system 100. The determined flat surface of one or more 2D patches is inputted to the backward mapping network depicted at 110C. The backward mapping network 110C predicts the corresponding three-dimensional (3D) position of the 2D points (u) that matches with the set of vertices of the mesh or the predicted assignment probability for all the vertices to each of the K patches 302.

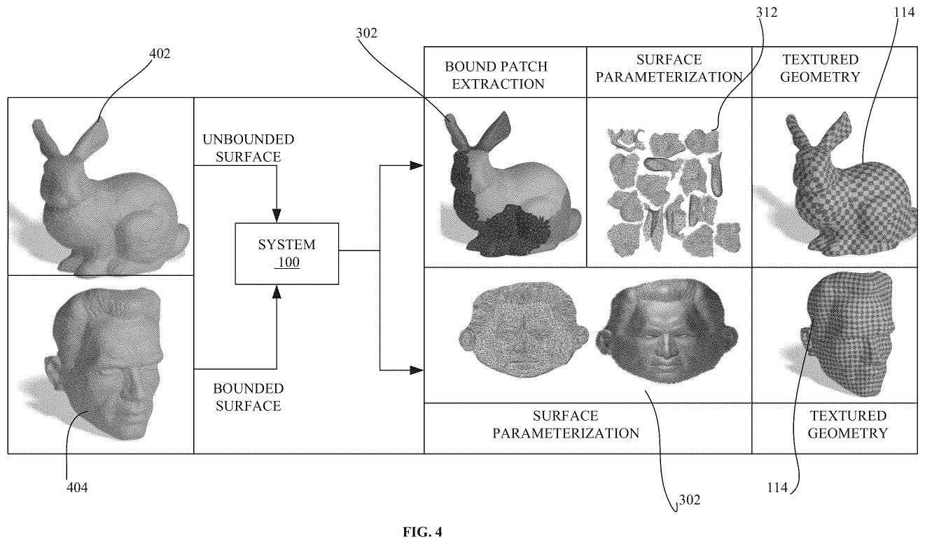

FIG. 4 is an exemplary diagram of surface parameterization for bounded patch and unbounded patch of the three-dimensional (3D) object according to some embodiments herein. The exemplary diagram of surface parameterization depicts the unbounded patch of the 3D object at 402. The exemplary diagram of surface parameterization depicts that if the system 100 receives the unbounded patch of the 3D object 402, (i) the unbounded patch of the 3D object 402 is partitioned into one or more bound patches by predicting assignment probability for all the vertices and the vertices to each of the K patches as depicted at 502 using the first machine learning model 108, (ii) parametrizing one or more bound patches as depicted at 312 by the second machine learning model 110, (iii) texture mapping on the one or more parameterized bound patches as depicted at 114. The exemplary diagram of surface parameterization depicts the bounded surface of the 3D object at 404. The exemplary diagram of surface parameterization depicts that if system 100 receives the bounded surface of the 3D object 404, (i) the bounded surface of the 3D object 404 is directly parameterized by the second machine learning model 11, (ii) the texture is mapped on the one or more parameterized bound patches as depicted at 114.

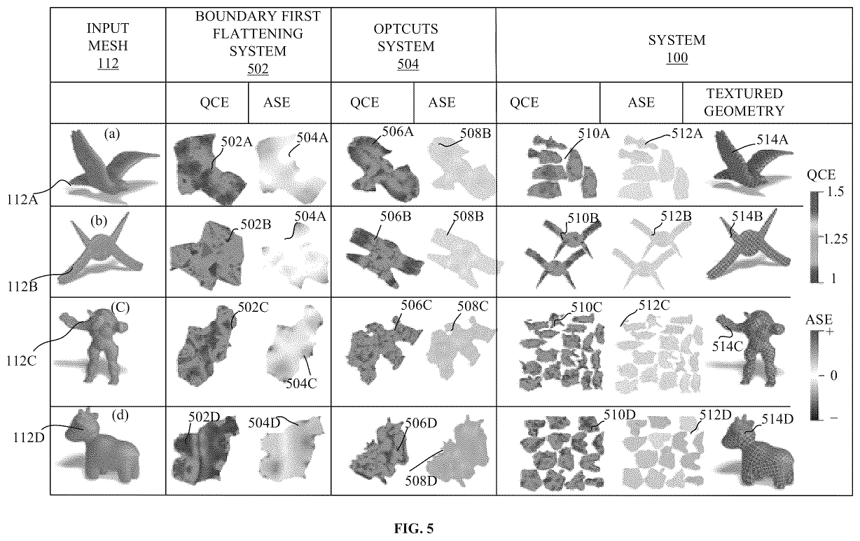

FIG. 5 is an exemplary diagram that illustrates a qualitative comparison between system and existing systems based on Quasi-Conformal Error (QCE) and Area Scale Error (ASE) metrics on a texture of a parameterized surface of an input mesh on specific classes of a Shape Retrieval Contest (SHREC) dataset according to some embodiments herein. The system 100 includes a first machine-learning model and a second machine-learning model that is a category-specific generalized network. The category-specific generalized network extracts diffusion features that represent characteristics of surfaces in the 3D object. The diffusion features are used in the surface parametrization. The exemplary diagram in FIG. 5 depicts an input mesh at 112 that is inputted to the system 100, a boundary-first flattening system 502, and an OptCuts system 504 to obtain a parameterized surface of the input mesh 112 for texture mapping. The input mesh 112 may be a 112A bird, pliers 112B, armadillo 112C, and spot 112D. The boundary-first flattening system 502, and the OptCuts system 504 are existing systems. In the boundary-first flattening system 502, the QCE or preserved areas of the parameterized surface of the input mesh 112 are depicted at 506A, 506B, 506C, and 506D during the texture mapping. In the boundary-first flattening system 502, the ASE or distortion areas of the parameterized surface of the input mesh 112 are depicted at 508A, 508B, 508C, and 508D during the texture mapping.

In the OptCuts system 504, the QCE or preserved areas of the parameterized surface of the input mesh 112 are depicted at 510A, 510B, 510C, and 510D during the texture mapping. In the OptCuts system 504, the ASE or distortion areas of the parameterized surface of the input mesh 112 are depicted at 512A, 512B, 512C, and 512D during the texture mapping.

In the system 100, the QCE or preserved areas of the parameterized surface of the input mesh 112 are depicted at 514A, 514B, 514C, and 514D during the texture mapping. In the system 100, the ASE or distortion areas of the parameterized surface of the input mesh 112 are depicted at 516A, 516B, 516C, and 516H during the texture mapping. In the system 100, textured geometries of the input mesh 112 are depicted at 518A, 518B, 518C, and 518D after the texture mapping.

The QCE is a metric that measures a degree to which local angles or areas on the surface of the input mesh 112 are preserved during the texture mapping process. The QCE is used to quantify how well a given parameterization (mapping from 3D surface to 2D texture) preserves local angles. The QCE is computed by comparing the angles in the 3D space of the input mesh 112 with the angles of the parameterized surface of the input mesh 112 in the 2D space.

The ASE measures the distortion in the areas of the triangles on the 3D surface of the input mesh 112 after the input mesh 112 is mapped to the 2D space as the parameterized surface. The ASE is calculated by comparing the areas of triangles of the input mesh 402 and the parameterized surface of the input mesh 112 to identify areas where distortion occurs in the parameterized surface of the input mesh 12.

Table: 1 depicts a quantitative comparison of metrics of the QCE and the ASE between the system 100 and the existing systems.

| | BFF | | Optcuts | | System 100 | |
|---|---|---|---|---|---|---|
| Class | QCE↓ | ASE↓ | QCE↓ | ASE↓ | QCE↓ | ASE↓ |
| Pliers | 1.112 | 1.909 | 1.128 | 1.391 | 1.274 | 2.895 |
| Rabbit | 1.132 | 2.116 | 1.160 | 2.062 | 1.183 | 0.992 |
| Scissors | 1.156 | 1.456 | 1.122 | 1.276 | 1.261 | 2.728 |
| Bird | 2.130 | 1.103 | 1.129 | 1.928 | 1.262 | 1.996 |

The boundary-first flattening system 502, and the OptCuts system 504 are not robust to noisy inputs or non-manifold meshes and are slow in processing large meshes which means the computational time of processing large meshes for obtaining the parameterized surface of the input mesh 502 is high. The system 100 performs the texture mapping on the parameterized surface of the input mesh 112 in a more organized and space-efficient manner as the system (i) partitioned the input mesh 112 into one or more bound patches using the first machine learning model, (ii) mapping one or more bound patches on the 2D space using the second machine learning model 110 to obtain accurate flat surface or parameterized surface of the input mesh 112.

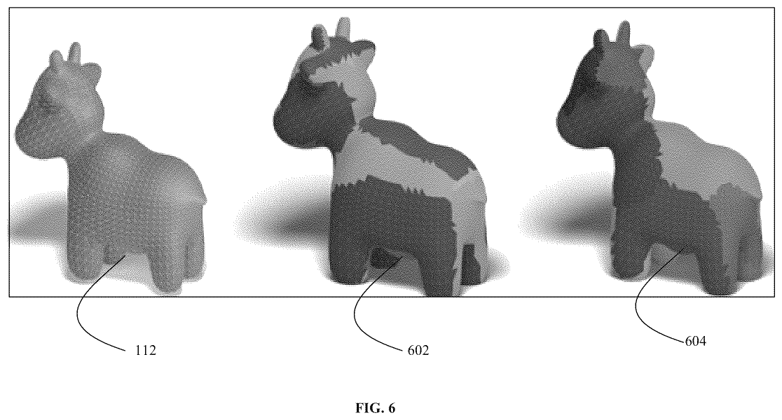

FIG. 6 is an exemplary diagram of an impact of incorporating the geodesic loss (Lgeo) into the objective function of patch extraction according to some embodiments herein. The exemplary diagram in FIG. 6 depicts the input mesh at 112 that is received through the user device 102. The exemplary diagram in FIG. 6 depicts one or more bound patches without geodesic loss at 602. This means the subset of faces that are associated with the subset of vertices of the one or more bound matches of the 3D object are geodesically far apart (i.e., the subset of faces is distant from each other in a geometric or spatial sense) but have high cosine similarity might erroneously be assigned to the same patch. This could lead to the creation of unwanted patches with extreme curvature. The exemplary diagram in FIG. 6 depicts one or more bound patches with the geodesic loss at 604. This means incorporating the geodesic loss (Lgeo) into the objective function of the patch extraction calculating for the shortest path between two points on a curved surface of the input mesh 112. By including the geodesic loss(Lgeo), the objective function of the patch extraction is modified to correct the subset of faces that are geodesically far apart but are assigned to the same patch. This correction is used to avoid a creation of unwanted patches with extreme curvature that improve an accuracy of the predicted assignment probability during the partition of the input mesh 112.

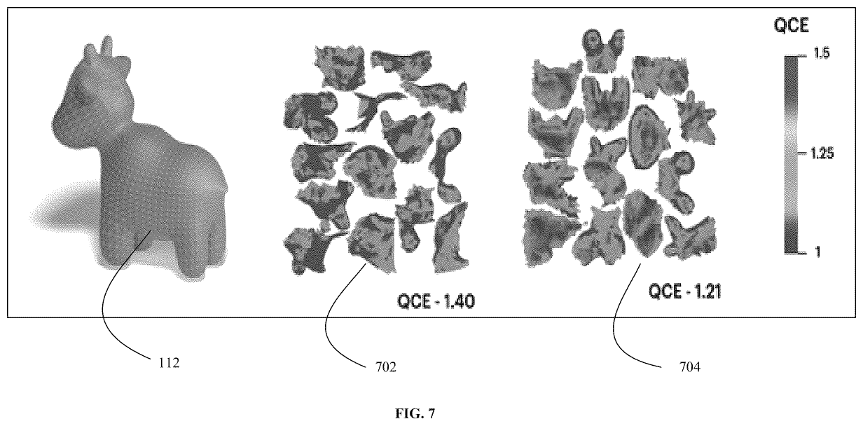

FIG. 7 is an exemplary diagram of the impact of using global shape encoding Vs per-vertex features by the diffusion block 110B of the second machine learning model 110 in regularizing a three-dimensional (3D) position of the 2D points (u) of the one or more bound patches in the two-dimensional (2D) plane during surface parameterization according to some embodiments herein. The exemplary diagram in FIG. 7 depicts the input mesh at 112 that is received through the user device 102. The exemplary diagram in FIG. 7 depicts the one or more parameterized patches of mesh 112 that are parameterized by the second machine learning model 110 that considers per vertex features of the one or more bound patches at 802 rather than considering the global shape encoding. The per-vertex features are noisy and provide the minimal global shape of the one or more bound patches, leading to the map of irregular UV coordinates of the one or more bound patches in the 2D plane (i.e Quasi-Conformal Error (QCE) is increased, for example, the QCE for the one or more parameterized patches of mesh without the global shape encoding is 1.40). The QCE 1.40 means the second machine learning model 110 may not preserve angles of the input mesh 112 during the mapping of each vertex in the one or more bound patches to 2D points on the 2D plane. The exemplary diagram in FIG. 7 depicts the one or more parameterized patches of mesh 112 that are parameterized by the second machine learning model 110 that considers the global shape encoding 704 during mapping. Thereby, the QCE is decreased to 1.21 which means the second machine learning model 110 preserves angles of the input mesh 112 during the mapping of each vertex in the one or more bound patches to 2D points on the 2D plane that leads to less distortion or overlapping.

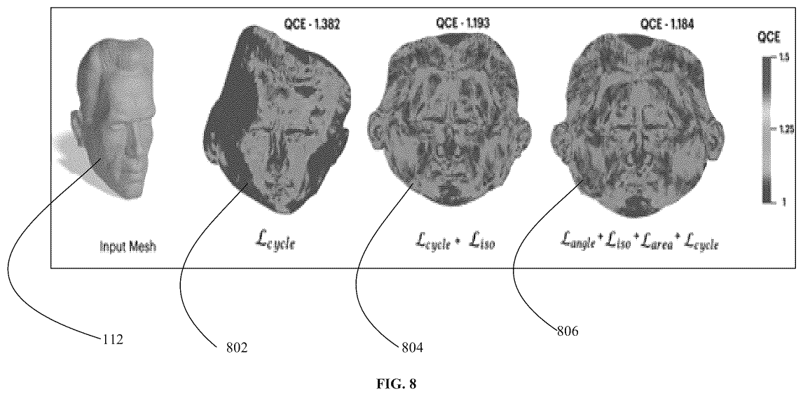

FIG. 8 is an exemplary diagram of ablation of different losses in the second machine learning model 110 during training of the surface parameterization of the input mesh parameterization according to some embodiments herein. The exemplary diagram in FIG. 8 depicts the input mesh at 112 that is received through the user device 102. The exemplary diagram in FIG. 8 depicts that the second machine learning model 110 is trained by cycle loss (L_{cycle}) initially at 802. The QCE is very high (i.e., 1.382) when the second machine learning model 110 is trained only by the cycle loss. The exemplary diagram in FIG. 8 depicts that the second machine learning model 110 is trained by both cycle loss (L_{cycle}) and isometric loss (L_{cycle}) at 804. The QCE is reduced to 1.193 from 1.382 when the second machine learning model 110 is trained by both cycle loss (L_{cycle}) and isometric loss (Lᵢₛₒ). This improves the quasi-conformal properties of the mapping, leading to better angle preservation. The exemplary diagram in FIG. 8 depicts that the second machine learning model 110 is trained by the cycle loss (L_{cycle}), the isometric loss (Lᵢₛₒ), area loss (Lₐᵣₑₐ), and angle loss (L_{angle}) at 806. The QCE is reduced to 1.184 from 1.193 when the second machine learning model 110 is trained by the cycle loss (L_{cycle}), the isometric loss (Lᵢₛₒ), the area loss (Lₐᵣₑₐ), and the angle loss (L_{angle}). This improves the mapping's characteristics of the second machine learning model 110, such as quasi-conformality and geometric properties like angular and area distortions.

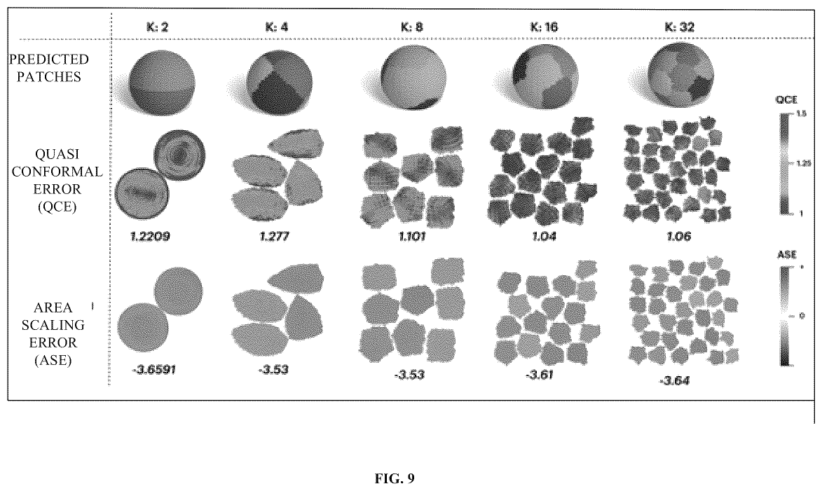

FIG. 9 is an exemplary diagram of obtaining one or more 2D patches from unbounded surfaces and how the one or more 2D patches impact conformal and angular distortion in the surface parameterization of the input mesh according to some embodiments herein. The exemplary diagram of FIG. 9 illustrates a trade-off between distortion, measured by values of the QCE and the ASE, and the number of patches that is if the number of patches increases, both conformal and angular distortion decrease. The conformal distortion means preserving angles in the mapping, and angular distortion is a measure of how well angles are preserved. For example, as shown in FIG. 9, if the number of patches (K) is increased from the K=2 to K=32, the QCE is decreased to 1.2209 to 1.06, and the ASR is reduced to −3.6591 to −3.64.

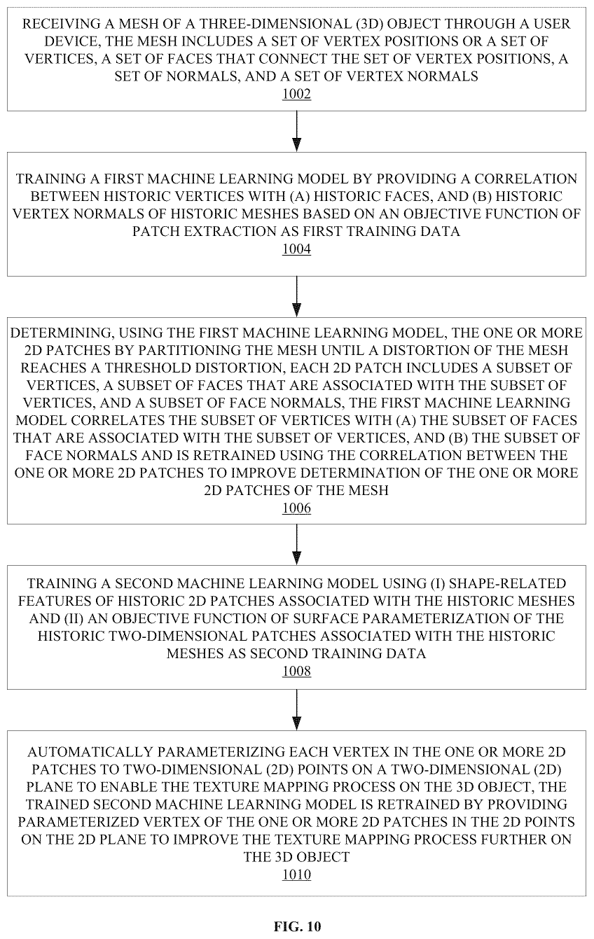

FIG. 10 is a flow diagram that illustrates a method for automatically determining one or more two-dimensional (2D) patches corresponding to a three-dimensional (3D) object using machine learning models according to some embodiments herein. At a step 1002, the method includes receiving a mesh of the 3D object through a user device. The mesh includes a set of vertex positions or vertices, a set of faces that connect the set of vertex positions, a set of normals, and a set of vertex normals. At a step 1004, the method includes training a first machine learning model by providing a correlation between historic vertices with (a) historic faces, and (b) historic vertex normals of historic meshes based on an objective function of patch extraction as first training data. At a step 1006, the method includes determining, using the first machine learning model, one or more 2D patches by partitioning the mesh until a distortion of the mesh reaches a threshold distortion. Each 2D patch includes a subset of vertices, a subset of faces that are associated with the subset of vertices, and a subset of face normal. The first machine learning model correlates the subset of vertices with (a) the subset of faces that are associated with the subset of vertices, and (b) the subset of face normals and is retrained using the correlation between the one or more 2D patches with the first training data to improve determination of the one or more 2D patches of the mesh. At a step 1008, the method includes training a second machine learning model using (i) shape-related features of historic 2D patches associated with the historic meshes and (ii) an objective function of surface parameterization of the historic two-dimensional patches associated with the historic meshes as second training data. At a step 1010, the method includes automatically parameterizing each vertex in the plurality of 2D patches to two-dimensional (2D) points on a two-dimensional (2D) plane to enable the texture mapping process on the 3D object, the second machine learning model is retrained by providing parameterized vertex of the plurality of 2D patches in the 2D points on the 2D plane to improve the texture mapping process further on the 3D object.

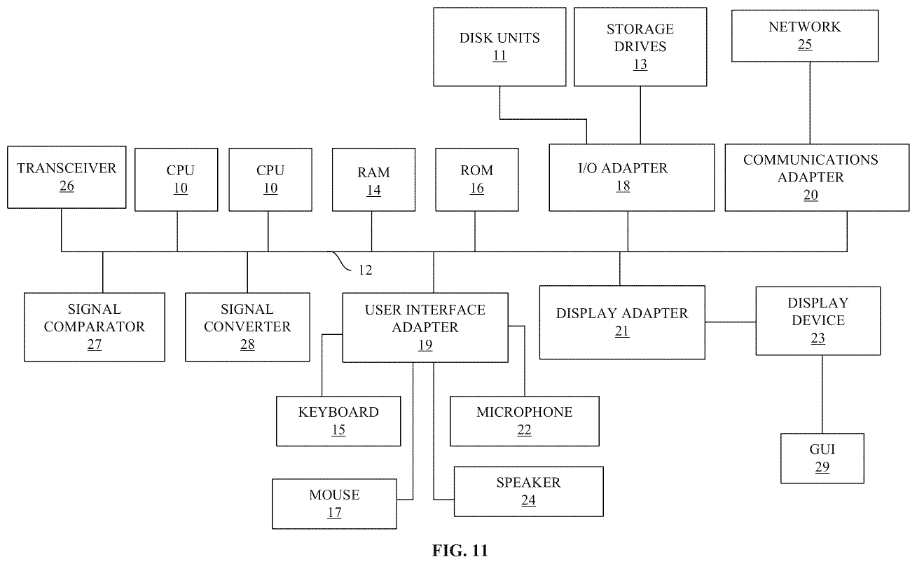

A representative hardware environment for practicing the embodiments herein is depicted in FIG. 11, with reference to FIGS. 1 through 10. This schematic drawing illustrates a hardware configuration of server 106/computer system/user device 104 in accordance with the embodiments herein. The user device includes at least one processing device 10 and a cryptographic processor 11. The special-purpose CPU 10 and the cryptographic processor (CP) 11 may be interconnected via system bus 14 to various devices such as a random access memory (RAM) 15, read-only memory (ROM) 16, and an input/output (I/O) adapter 17. The I/O adapter 17 can connect to peripheral devices, such as disk units 12 and tape drives 13, or other program storage devices that are readable by the system. The user device can read the inventive instructions on the program storage devices and follow these instructions to execute the methodology of the embodiments herein. The user device further includes a user interface adapter 20 that connects a keyboard 18, mouse 19, speaker 25, microphone 23, and/or other user interface devices such as a touch screen device (not shown) to the bus 14 to gather user input. Additionally, a communication adapter 21 connects the bus 14 to a data processing network 26, and a display adapter 22 connects the bus 14 to a display device 24, which provides a graphical user interface (GUI) 30 of the output data in accordance with the embodiments herein, or which may be embodied as an output device such as a monitor, printer, or transmitter, for example. Further, a transceiver 27, a signal comparator 28, and a signal converter 29 may be connected with the bus 14 for processing, transmission, receipt, comparison, and conversion of electric or electronic signals.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope.

What is claimed is:

1. A processor-implemented method for automatically determining a plurality of two-dimensional (2D) patches corresponding to a three-dimensional (3D) object using machine learning models for enabling an improved texture mapping process on the 3D object, wherein the method comprises:
receiving a mesh of the 3D object through a user device, wherein the mesh comprises a set of vertex positions or a set of vertices, a set of faces that connect the set of vertex positions, a set of normals, and a set of vertex normals;
training a first machine learning model by providing a correlation between historic vertices with (a) historic faces, and (b) historic vertex normals of historic meshes based on an objective function of patch extraction as first training data;
determining, using the first machine learning model, the plurality of 2D patches by partitioning the mesh until a distortion of the mesh reaches a threshold distortion, wherein each 2D patch comprises a subset of vertices, a subset of faces that are associated with the subset of vertices, and a subset of face normals, wherein the first machine learning model correlates the subset of vertices with (a) the subset of faces that are associated with the subset of vertices, and (b) the subset of face normals and is retrained using the correlation between the plurality of 2D patches with the first training data to improve determination of the plurality of 2D patches of the mesh;
training a second machine learning model using (i) shape-related features of historic 2D patches associated with the historic meshes and (ii) an objective function of surface parameterization of the historic two-dimensional patches associated with the historic meshes as second training data; and
automatically parameterizing each vertex in the plurality of 2D patches to two-dimensional (2D) points on a two-dimensional (2D) plane to enable the texture mapping process on the 3D object, wherein the second machine learning model is retrained by providing a parameterized vertex of the plurality of 2D patches in the 2D points on the 2D plane to improve the texture mapping process further on the 3D object.

2. The processor-implemented method of claim 1, wherein the objective function of the patch extraction comprises at least one of a cosine similarity constraint, or a geodesic distance constraint, wherein the cosine similarity constraint is determined by calculating a cosine similarity between normal vectors of the historic faces within the historic meshes, wherein the geodesic distance constraint is determined by calculating a shortest path between the historic vertices within the historic meshes based on the cosine similarity between the normal vectors of the historic faces.

3. The processor-implemented method of claim 1, wherein the second machine learning model comprises a forward mapping network associated with a diffusion block and a backward mapping network.

4. The processor-implemented method of claim 1, wherein the method further comprises mapping each vertex to the 2D points on the 2D plane by (i) receiving a subset of vertices of the plurality of 2D patches through the forward mapping network, (ii) processing, using the backward mapping network, the subset of vertices through the diffusion block to obtain the shape-related features or relationships between a plurality of features of the plurality of 2D patches, and (iii) mapping each vertex to the 2D points on the 2D plane based on the shape-related features of the plurality of 2D patches.

5. The processor-implemented method of claim 1, wherein the method further comprises predicting, by the backward mapping network, a three-dimensional position of the 2D points that matches with the set of vertices of the mesh.

6. The processor-implemented method of claim 1, wherein the objective function of the surface parameterization comprises at least one of a cycle consistency loss, an isometric loss, an angle preservation loss, or an area preservation loss.

7. The processor-implemented method of claim 1, wherein the method further comprises partitioning the mesh by (i) receiving the set of vertex normals and the set of vertices of the mesh, (ii) predicting probabilities of the set of vertices associated with the plurality of 2D patches by processing the set of vertex normals and the set of vertices, (iii) obtaining the probabilities of the set of faces by averaging neighboring probabilities of the set of vertices for each face, and (iv) partitioning the mesh by assigning the set of faces into the plurality of 2D patches based on the probabilities of the set of vertices, wherein the probabilities of the set of vertices are predicted by analyzing surface characteristics of the mesh at a multi-scale characterization.

8. The processor-implemented method of claim 1, wherein the method further comprises implementing the multi-scale characterization by determining the plurality of features from the set of vertices of the mesh at a finer level or a coarse level by analyzing the mesh using a diffusion network in the first machine learning model.

9. The method of claim 1, wherein the mesh is comprised of a single patch if the surface of the mesh has a low variability in an extrinsic curvature.

10. A system for automatically determining a plurality of two-dimensional (3D) patches corresponding to a three-dimensional (3D) object using machine learning models for enabling an improved texture mapping process on the 3D object, wherein the system comprising:
a server receives a mesh of the 3D object through a user device, wherein the mesh comprises a set of vertex positions or a set of vertices, a set of faces that connect the set of vertex positions, a set of normals, and a set of vertex normals, wherein the server comprises
a memory that stores a set of instructions; and
a processor that executes the set of instructions and is configured to,
train a first machine learning model by providing a correlation between historic vertices with (a) historic faces, and (b) historic vertex normals of historic meshes based on an objective function of patch extraction as first training data;
determine, using the first machine learning model, the plurality of 2D patches by partitioning the mesh until a distortion of the mesh reaches a threshold distortion, wherein each 2D patch comprises a subset of vertices, a subset of faces that are associated with the subset of vertices, and a subset of face normals, wherein the first machine learning model correlates the subset of vertices with (a) the subset of faces that are associated with the subset of vertices, and (b) the subset of face normals and is retrained using the correlation between the plurality of 2D patches with the first training data to improve determination of the plurality of 2D patches of the mesh;
train a second machine learning model using (i) shape-related features of historic 2D patches associated with the historic meshes and (ii) an objective function of surface parameterization of the historic two-dimensional patches associated with the historic meshes as second training data; and
automatically parameterize each vertex in the plurality of 2D patches to two-dimensional (2D) points on a two-dimensional (2D) plane to enable the texture mapping process on the 3D object, wherein the second machine learning model is retrained by providing a parameterized vertex of the plurality of 2D patches in the 2D points on the 2D plane to improve the texture mapping process further on the 3D object.

11. The system of claim 10, wherein the objective function of the patch extraction comprises at least one of a cosine similarity constraint, or a geodesic distance constraint, wherein the cosine similarity constraint is determined by calculating a cosine similarity between normal vectors of the historic faces within the historic meshes, wherein the geodesic distance constraint is determined by calculating a shortest path between the historic vertices within the historic meshes based on the cosine similarity between the normal vectors of the historic faces.

12. The system of claim 10, wherein the second machine learning model comprises a forward mapping network associated with a diffusion block and a backward mapping network.

13. The system of claim 11, wherein the processor is further configured to map each vertex to the 2D points on the 2D plane by (i) receiving the subset of vertices of the plurality of 2D patches through the forward mapping network, (ii) processing, using the backward mapping network, the subset of vertices through the diffusion block to obtain overall shape-related features or relationships between a plurality of features of the plurality of 2D patches, and (iii) mapping each vertex to the 2D points on the 2D plane based on the shape-related features of the plurality of 2D patches.

14. The system of claim 10, wherein the processor is further configured to predict, by the backward mapping network, a three-dimensional position of the 2D points that matches with the set of vertices of the mesh.

15. The system of claim 10, wherein the objective function of the surface parameterization comprises at least one of a cycle consistency loss, an isometric loss, an angle preservation loss, or an area preservation loss.

16. The system of claim 10, wherein the processor is further configured to partition the mesh by (i) receiving the set of vertex normals and the set of vertices of the mesh, (ii) predicting probabilities of the set of vertices associated with the plurality of bound patches by processing the set of vertex normals and the set of vertices, (iii) obtaining the probabilities of the set of faces by averaging neighboring probabilities of the set of vertices for each face, and (iv) partitioning the mesh by assigning the set of faces into the plurality of bound patches based on the probabilities of the set of vertices, wherein the probabilities of the set of vertices are predicted by analyzing surface characteristics of the mesh at a multi-scale characterization.

17. The system of claim 10, wherein the processor is further configured to implement the multi-scale characterization by determining the plurality of features from the set of vertices of the mesh at a finer level or a coarse level by analyzing the mesh using a diffusion network in the first machine learning model.

18. The system of claim 10, wherein the mesh is comprised of a single patch if the surface of the mesh has a low variability in an extrinsic curvature.

19. One or more non-transitory computer-readable storage mediums storing one or sequences of instructions, which when executed by one or more processors, causes a method for automatically determining a plurality of two-dimensional (2D) patches corresponding to a three-dimensional (3D) object using machine learning models for enabling an improved texture mapping process on the 3D object, wherein the method comprises:
receiving a mesh of the 3D object through a user device, wherein the mesh comprises a set of vertex positions or a set of vertices, a set of faces that connect the set of vertex positions, a set of normals, and a set of vertex normals;
training a first machine learning model by providing a correlation between historic vertices with (a) historic faces, and (b) historic vertex normals of historic meshes based on an objective function of patch extraction as first training data;
determining, using the first machine learning model, the plurality of 2D patches by partitioning the mesh until a distortion of the mesh reaches a threshold distortion, wherein each 2D patch comprises a subset of vertices, a subset of faces that are associated with the subset of vertices, and a subset of face normals, wherein the first machine learning model correlates the subset of vertices with (a) the subset of faces that are associated with the subset of vertices, and (b) the subset of face normals and is retrained using the correlation between the plurality of 2D patches with the first training data to improve determination of the plurality of 2D patches of the mesh;
training a second machine learning model using (i) shape-related features of historic 2D patches associated with the historic meshes and (ii) an objective function of surface parameterization of the historic two-dimensional patches associated with the historic meshes as second training data; and
automatically parameterizing each vertex in the plurality of 2D patches to two-dimensional (2D) points on a two-dimensional (2D) plane to enable the texture mapping process on the 3D object, wherein the second machine learning model is retrained by providing a parameterized vertex of the plurality of 2D patches in the 2D points on the 2D plane to improve the texture mapping process further on the 3D object.
